(19) United States
(12) Patent Application Publication
(10) Pub. No.: US 2006/0081843 A1
(43) Pub. Date: Apr. 20, 2006

(54) Semiconductor article and method for manufacturing the same

(76) Inventor: Christoph Bromberger, Heilbronn (DE)

Correspondence Address: BIRCH STEWART KOLASCH & BIRCH, PO BOX 747, FALLS CHURCH, VA, 22040-0747, US

(21) Appl. No.: 11/251,865

(22) Filed: Oct. 18, 2005

(30) Foreign Application Priority Data
Oct. 19, 2004 (DE) DE 102004050740.6

(51) Int. Cl. H01L 29/02; H01L 21/38

(52) U.S. Cl. 257/49; 438/558; 438/561; 438/682; 257/565; 148/33.3

(57) ABSTRACT

Method for manufacturing a semiconductor article, in that a silicide layer is applied, an impurity which acts as a dopant in a semiconductor region is introduced into the silicide layer, the silicide layer being located at least partially beneath the monocrystalline semiconductor region adjacent to the silicide layer, so that the silicide layer is at least partially buried beneath a layer of the monocrystalline semiconductor region, whereby, via a later high-temperature step, the impurity which acts as a dopant is at least partially diffused into the adjacent monocrystalline semiconductor region from the at least partially buried silicide layer.

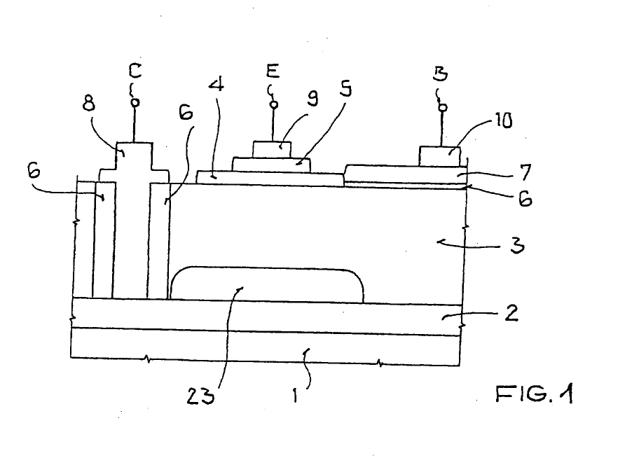

This nonprovisional application claims priority under 35 U.S.C. §119(a) on German Patent Application No. DE 102004050740.6, which was filed in Germany on Oct. 19, 2004, and which is herein incorporated by reference.

### BACKGROUND OF THE INVENTION

1. Field of the Invention

The present invention relates to a semiconductor article and a method for manufacturing the semiconductor article.

2. Description of the Background Art

A method for manufacturing buried areas is known from the document DE 101 24 038 A1, which corresponds to U.S. Pat. No. 6,720,238. In this method, an SOI wafer has a substrate of silicon adjoined by an oxide layer as an insulating layer with a thickness between 0.1 μm and 2.0 μm. The oxide layer is adjacent to a layer of silicon that is divided by means of an implantation into a first region with a first conductivity type and a second region with a second conductivity type. In a subsequent step, a continuous oxide layer is applied to the surface of the SOI wafer; by means of a mask step, openings are etched in this oxide layer through which a silicide is produced in a subsequent process step. In this regard, the thickness of the oxide layer is chosen such that it forms a planar surface together with the silicidized regions. Next, a second oxide layer is applied and a second carrier wafer is bonded onto the second oxide layer. Thereafter, the first carrier wafer and the first oxide layer are removed.

According to DE 101 24 038 A1, the bulk resistance in connecting to a monocrystalline semiconductor region includes a junction resistance between the buried silicide region and the monocrystalline semiconductor region in addition to a sheet resistance of the buried silicide region. In this regard, the junction between the buried silicide region and the monocrystalline semiconductor region is a high-resistance contact known as a Schottky contact for low to moderately high dopant concentrations in the monocrystalline semiconductor region at the boundary with the buried silicide region, and is only of the low-resistance type, called ohmic, at high to very high dopant concentrations.

It is not always advantageous to provide the monocrystalline semiconductor region with a high dopant concentration at the boundary with the buried silicide layer when depositing it, namely due to disadvantageously high out-diffusion from highly doped semiconductor regions under exposure to heat. Likewise, it is frequently disadvantageous to create a high dopant concentration in the monocrystalline semiconductor region at the boundary with the buried silicide region by implantation in the monocrystalline semiconductor region, on account of the relatively wide Gaussian distribution of dopants introduced by deep implantation.

From EP 0 712 155 A2, EP 0 494 598 B1, and JP 59181636 A, respectively, production methods for a semiconductor component having a buried silicide layer are known. Because the diffusion distance at 1000° C. is about 200 times greater in the silicide than a diffusion distance in the monocrystalline silicone, the dopants diffuse more rapidly in the silicide than in the monocrystalline silicone. Taking advantage of this effect, the silicide is utilized as the diffusion path, whereby simultaneously dopants from a heavily doped area of a semiconductor region diffuse into the silicide, and in a low-doped area of a semiconductor area, they diffuse out of the silicide layer. A special method for the burying of a silicide layer is disclosed in DE 101 24 038 A1.

U.S. Pat. No. 5,643,821 discloses that a silicide layer is formed on a surface of an epitaxial layer. Then a P-type substrate is bonded to the other side of the silicide layer. Thereafter a trench is formed in the epitaxial layer, whererby the silicide layer functions as a etch stop. Then a N+ dopant can be introduced directly through the trench structures into the silicide. However, because a substantial surface area of the silicide is covered by the eiptaxial layer, the N+ dopant cannot be injected over a substantial portion of the silicide area and a lateral diffusion is required. Thus, it is not possible to provide a sufficient amount of N+ dopant over the entire silicide layer and a high dosage amount of the N+ dopant is required, which amourphorizes the silicide area exposed in the trench structures. Furthermore, because the P-type substrate is bonded to the silicide layer, manufacturing costs increase significantly.

The range of process design options in the production of a semiconductor article are thus clearly limited by the prior art capabilities for designing a junction resistance between a buried silicide layer and a monocrystalline semiconductor region.

### SUMMARY OF THE INVENTION

It is therefore an object of the present invention to provide a method for designing the junction resistance between a buried silicide layer and an adjacent semiconductor region to be ohmic while avoiding the disadvantages of the prior art as far as possible.

Accordingly, a method for producing a semiconductor article is provided. In this method, a silicide layer is deposited and one or more impurities are introduced into the silicide layer and over a substantial portion of the surface area. Once these impurities have diffused into adjacent semiconductor regions, they act as dopants. Accordingly, such impurities are preferably the dopants that are usable for silicon semiconductors, such as, for example, boron, arsenic, phosphorus, etc. In the silicide, the atoms that later diffuse into the silicon and constitute there a dopant and are thus impurities.

The silicide layer is located at least partially beneath a monocrystalline semiconductor region adjacent to the silicide layer. The arrangement is made such that the silicide layer is at least partially buried beneath a layer of the monocrystalline semiconductor region. Via a later high-temperature step, the one or more impurities which act as dopants are at least partially diffused into the adjacent monocrystalline semiconductor region from the at least partially buried silicide layer.

Thus, in this method for manufacturing the semiconductor article, the silicide layer provided with at least one impurity serves as a solid source for doping the monocrystalline semiconductor region covering the silicide layer, where this impurity serves as a dopant. The monocrystalline semiconductor region to be doped is adjacent to the silicide layer in this context.

Two variants of further developments of the invention, which are discussed below, can be used in this regard. In the first variant, the silicide layer is deposited and at least one region of the silicide layer is introduced beneath the previously structured monocrystalline semiconductor region. In a later high-temperature step, the one or more impurities which act as dopants in the semiconductor material are at least partially diffused into the adjacent monocrystalline semiconductor region from the buried silicide layer.

In contrast, in the second variant, the silicide layer is deposited and is at least partially covered by the subsequently deposited monocrystalline semiconductor region in such a manner that the silicide layer is at least partially buried beneath a layer of the monocrystalline semiconductor region. In a later high-temperature step, the one or more impurities which act as dopants in the semiconductor material are in turn at least partially diffused into the adjacent monocrystalline semiconductor region from the at least partially buried silicide layer.

In a process step according to a further embodiment of the invention, one or more impurities, which act as dopants in the semiconductor material, are introduced. Dopants for a silicon semiconductor can be boron atoms, phosphorus atoms, arsenic atoms, or antimony atoms, for example. The silicide layer is preferably completely buried under a layer. This layer preferably includes the monocrystalline semiconductor region that is adjacent to the silicide layer.

These process steps are preferably performed in the stated order, wherein additional process steps, for example an implantation or a planarization, can take place between the individual process steps. In the following, it is to be understood with regard to the buried silicide layer that this silicide layer is arranged at least partially beneath at least one active monocrystalline semiconductor region of a semiconductor component. In a subsequent high-temperature step, the dopants are at least partially diffused into the adjacent monocrystalline semiconductor region (from the buried silicide layer).

Thus, a silicide layer can be used as dopant source, where it is important that this silicide layer advantageously has already been partially, and preferably completely, buried during the diffusion of the dopants. Accordingly, the buried silicide layer, which is provided with impurities for this purpose, is used as a solid source for the doping of the semiconductor region adjacent to the silicide layer. The semiconductor region that at least partially covers the silicide layer is preferably located completely above the silicide layer with respect to the wafer surface.

An embodiment of the invention provides that in a boundary region of the monocrystalline semiconductor region adjacent to the silicide layer, the dopants can be diffused in such a manner that a junction resistance between the monocrystalline semiconductor region and the silicide layer is ohmic. In this context, ohmic junction resistance is understood to mean that the charge carriers crossing the junction resistance do not have to overcome any significant potential barrier.

Moreover, provision is preferably made that a maximum dopant concentration of at least 1·10²⁰ cm⁻³ is diffused into the boundary region. In order to provide the silicide layer with the impurities, which will later act as dopants, for the desired out-diffusion, different example embodiments of the invention are provided; these example embodiments can also be locally combined with one another, for example as a function of a suitable masking.

A first example embodiment provides that the impurities are implanted in the silicide layer. This can take place after a silicidization of a layer of a silicon semiconductor surface, for example.

In a second example embodiment, the introduction of the impurities and the application of the silicide layer take place by substantially simultaneous sputtering of a dopant target and a silicide target. It is also possible, in a third example embodiment, to introduce the impurities and apply the silicide layer by sputtering a silicide target provided with the impurities.

A further embodiment of the invention provides that the semiconductor region is grown in a monocrystalline fashion on the silicide layer. Preferably, monocrystalline silicon is epitaxially applied to the silicide layer. Molecular beam epitaxy or organometallic deposition methods can be used with advantage to this end.

In a preferred embodiment of the invention, monocrystalline semiconductor material is applied on the silicide layer at a thickness that permits the arrangement of an active semiconductor component above the silicide layer. The semiconductor component preferably has pn junctions within the thickness of the semiconductor material.

Another aspect of the invention is a method for manufacturing a connecting trace with a layered structure having a length in the range between a minimum length and a maximum length, said connecting trace consisting in particular of a silicon layer and a silicide layer, in that: a silicon layer with a dopant concentration N_{BL} is prepared; a layer of a silicide provided with one or more impurities which lies under or on the silicon layer is prepared, wherein the impurities act as dopants in an adjacent semiconductor material; a portion of the one or more impurities is diffused out of the silicide layer into the silicon layer through heat treatment; wherein the dopants function as doping agents for silicon; the layer overlap does not exceed a maximum length measured in microns of 2e20 divided by the dopant concentration N_{BL} in cm⁻³. The layer overlap preferably has a minimum length of 1 μm.

As a result of the manufacturing process specified here, the surface concentration in the contacted silicon layer at the junction with the contacting silicide trace for low-doped contacted silicon layers can be raised significantly above the dopant concentration in the interior of the contacted silicon layer, thus reducing the contact resistance.

Another aspect of the invention relates to a semiconductor article with a buried silicide layer, which is adjacent to a monocrystalline semiconductor region. The monocrystalline semiconductor region here is doped by doping agents which have diffused out of the silicide layer acting as a dopant source.

Preferably, a junction resistance between the monocrystalline semiconductor region and the silicide layer has ohmic character, wherein the junction resistance is preferably less than 1 mOhm cm², especially preferably less than 0.1 mOhm cm².

A preferred further development of the invention provides that the silicide layer is at least partially covered by the monocrystalline semiconductor material, and that preferably the lowest junction resistance is formed between the silicide layer and the semiconductor region located thereupon.

In further development of the invention, provision is made that the silicide layer is at least partially overgrown in a monocrystalline fashion by semiconductor material of the semiconductor region, wherein preferably the lattice of the silicide layer is continued by the lattice of the semiconductor region.

The semiconductor region is preferably part of an active component. In order to permit the flow of current through the junction resistance between the silicide layer and the monocrystalline semiconductor region, the silicide layer is preferably connected to a metallic contact at a distance from the boundary surface with the monocrystalline semiconductor region.

Another aspect of the invention is a use of an above-described manufacturing process to produce a high-frequency component or a high-voltage component having an active semiconductor region connected with low resistance by a silicide layer.

Another aspect of the invention is a high-frequency bipolar transistor having an emitter semiconductor region, a base semiconductor region and a collector semiconductor region. The collector semiconductor region is adjacent to a silicide layer that is at least partially buried under the collector semiconductor region. The portion of the collector semiconductor region adjacent to the silicide layer is highly doped by doping agents that have diffused out of the silicide layer.

The invention is described in detail using an example embodiment with the aid of a graphical representation. Here, the figure shows a schematic representation of a semiconductor article which constitutes a bipolar transistor.

The bulk resistance includes, in addition to a sheet resistance of a buried silicide region, a junction resistance between the buried silicide region and an adjacent monocrystalline semiconductor region that is intended to act as an active region of a component. In this regard, the junction between the buried silicide region and the monocrystalline semiconductor region is a high-resistance contact known as a Schottky contact for low to moderately high dopant concentrations in the monocrystalline semiconductor region at the boundary with the buried silicide region. The contact is only of the low-resistance type, called ohmic, at high to very high dopant concentrations.

On account of the out-diffusion from highly-doped semiconductor regions under exposure to high temperatures, it is not always desirable to provide the monocrystalline semiconductor region with a high dopant concentration at the boundary with the buried silicide region when depositing it. In order to permit this, an example embodiment of a manufacturing process is given with the aid of the figure. This process has the advantage that it is not necessary to produce a high dopant concentration in the monocrystalline semiconductor region at the boundary with the buried silicide region after the fact by implantation. In addition, the relatively wide Gaussian distribution of dopants introduced by deep implantation is avoided.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawing which are given by way of illustration only, and thus, are not limitive of the present invention, and wherein the sole figure illustrates a cross section of an embodiment of the present invention.

### DETAILED DESCRIPTION

Starting from the surface of the wafer, the substrate 1 is at the bottom, wherein the substrate can include monocrystalline semiconductor material, for example silicon, or an insulator. A silicide layer 2, for example titanium silicide, tantalum silicide, cobalt silicide or tungsten silicide, is deposited on this substrate 1, for example by sputtering of a silicide target.

In a manufacturing process, this silicide layer is designed as a dopant source for subsequent process steps, in that prior to the deposition of additional layers (above this silicide layer 2) there is implanted in this silicide layer 2 a high dose of impurities which can act as dopants of a first conductivity type, for example n-type, in an adjacent semiconductor region.

The silicide layer 2 is buried by the subsequent deposition of a monocrystalline silicon semiconductor layer 3, which is likewise of the first conductivity type. In order to contact the silicide layer 2, a metallization 8 is introduced into an opening etched in the monocrystalline silicon semiconductor layer 3. In order to isolate the metallization from the monocrystalline silicon semiconductor layer 3, the region of the monocrystalline silicon semiconductor layer 3 is covered with a thermal oxide 6.

During the oxidation to form the thermal oxide 6, the temperature and duration of the oxidation are designed such that the dopants previously implanted in the silicide layer 2 diffuse into the adjacent monocrystalline silicon semiconductor layer 3 and form a low-resistance junction resistance between the monocrystalline silicon semiconductor layer 3 and the silicide layer 2. To this end, the dopants diffuse into a boundary region 23 that is adjacent to the silicide layer 2 and is critical for the junction resistance, in such a manner that this boundary layer 23 has a maximum dopant concentration of at least 1·10²⁰ cm⁻³.

Next, a SiGe semiconductor layer 4 of a second conductivity type (p-type) is deposited. This borders on a silicide layer 7 of TiSi₂, which in turn borders on a metallization 10. Dopants of the second conductivity type are likewise introduced into the unburied silicide layer 7, and diffuse into the SiGe semiconductor layer 4 during a thermal exposure. A silicon semiconductor layer 5 of the first conductivity type is in turn deposited on the SiGe semiconductor layer 4, and is contacted by a metallization 9. The metallizations 8, 9 and 10 here form the collector connection C, the emitter connection E, and the base connection B, respectively. By way of example, the example embodiment shown in the figure shows a high-frequency npn bipolar transistor with the conductivity types shown.

An advantageous feature of this example embodiment is that an impurity is introduced into the buried silicide layer 2 or parts of the buried silicide layer 2, and under thermal exposure the impurity diffuses into the semiconductor region 23 adjacent to the silicide layer 2, where it functions as a dopant. This makes it possible to reduce the connection resistance. The connection resistance here has the primary components of a line resistance of the silicide layer 2 and a junction resistance between the monocrystalline semiconductor region 3 and the silicide region 2. In order to bring the junction resistance between the monocrystalline semiconductor region 3 and the silicide region 2 into the low-resistance, ohmic region, a dopant concentration greater than 1·10²⁰ cm⁻³ is achieved in the boundary region between the silicide region 2 and the adjacent semiconductor region 23 in the example embodiment shown in the figure. This achieves a low lateral diffusion of the dopants, in that the thermal budget of this described method can be kept relatively small as a whole.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for manufacturing a semiconductor article, the method comprising the steps of:
applying a silicide layer;
introducing an impurity, which acts as a dopant in a monocrystalline semiconductor region, into the silicide layer and over a substantial area of the silicide layer;
providing the silicide layer at least partially beneath the monocrystalline semiconductor region, which is adjacent to the silicide layer, so that the silicide layer is at least partially buried beneath a layer of the monocrystalline semiconductor region; and
partially diffusing, via a subsequent high-temperature step, the impurity that acts as a dopant, into the adjacent monocrystalline semiconductor region from the at least partially buried silicide layer.

2. The method according to claim 1, wherein the monocrystalline semiconductor region is structured, wherein, with the deposition of the silicide layer, at least a part of the silicide layer is introduced under the previously structured monocrystalline semiconductor region, and wherein, in the later high-temperature step, the impurity which acts as a dopant is at least partially diffused into the adjacent structured monocrystalline semiconductor region from the buried silicide layer.

3. The method according to claim 1, wherein the deposited silicide layer is at least partially covered by the monocrystalline semiconductor region, which is subsequently deposited, in such a manner that the silicide layer is at least partially buried beneath a layer of the monocrystalline semiconductor region, and wherein, in the later high-temperature step, the impurity which acts as a dopant is at least partially diffused into the monocrystalline semiconductor region from the silicide layer.

4. The method according to claim 1, wherein the impurity is diffused into a boundary region of the monocrystalline semiconductor region that is adjacent to the silicide layer so that a junction resistance between the monocrystalline semiconductor region and the silicide layer is ohmic.

5. The method according to claim 4, wherein a dopant concentration of at least 1·10²⁰ cm⁻³ is diffused into the boundary region that is effective for the junction resistance.

6. The method according to claim 1, wherein the impurity is implanted in the silicide layer.

7. The method according to claim 1, wherein the introduction of the impurity and the application of the silicide layer are performed by substantially simultaneous sputtering of a dopant target and a silicide target.

8. The method according to claim 1, wherein the introduction of the impurity and the application of the silicide layer are performed by sputtering of a silicide target provided with the impurity.

9. The method according to claim 1, wherein the semiconductor region is grown in a monocrystalline fashion on the silicide layer.

10. The method according to claim 1, wherein monocrystalline silicon is epitaxially applied to the silicide layer.

11. The method according to claim 10, wherein the monocrystalline silicon is applied with a thickness of at least 0.1 μm.

12. A method for manufacturing a connecting trace with a layered structure having a length, the connecting trace having a silicon layer and a silicide layer, the method comprising the steps of:
preparing a silicon layer with a dopant concentration N_{BL};
providing a layer of a silicide with an impurity, the silicide being formed under or on the silicon layer, wherein the impurity acts as a dopant in the silicon layer that is adjacent to the silicide; and
diffusing a portion of the impurity out of the silicide layer into the silicon layer through heat treatment,
wherein the dopant is a doping agent for adjacent silicon, and
wherein a layer overlap does not exceed a maximum length measured in microns of 2e20 divided by the dopant concentration N_{BL} in cm⁻³.

13. The method according to claim 12, wherein the layer overlap has a minimum length of 1 μm.

14. Use of a silicide layer located at least partially beneath a monocrystalline semiconductor region, the silicide layer being provided with an impurity across a substantial surface area thereof and serving, in a method for manufacturing a semiconductor article, as a solid source for doping at least the semiconductor region located above the silicide layer, wherein the impurity diffusing out of the silicide layer acts as a dopant in adjacent semiconductor regions.

15. A semiconductor article having a buried silicide layer adjacent to a monocrystalline semiconductor region, wherein the monocrystalline semiconductor region is doped by a dopant which has diffused out of the buried silicide layer, which is a dopant source, the dopant being provided across a substantial surface area of the buried silicide layer.

16. The semiconductor article according to claim 14, wherein a junction resistance between the monocrystalline semiconductor region and the silicide layer is ohmic.

17. The semiconductor article according to claim 16, wherein the junction resistance is less than 1 mOhm cm².

18. The semiconductor article according to claim 14, wherein the silicide layer is at least partially covered by the monocrystalline semiconductor material.

19. The semiconductor article according to claim 18, wherein the silicide layer is at least partially overgrown in a monocrystalline fashion by semiconductor material of the semiconductor region continuing a lattice of the silicide layer.

20. The semiconductor article according to claim 14, wherein the semiconductor region is a part of an active component.

21. The semiconductor article according to claim 14, wherein the silicide layer is connected to a metallic contact.

22. The method according to claim 1, wherein the semiconductor article is a component of a high-frequency component having and active semiconductor region connected with low resistance by a silicide layer.

23. The method according to claim 1, wherein the semiconductor article is a component of a high-voltage component having an active semiconductor region connected with low resistance by a silicide layer.

24. A high frequency bipolar transistor comprising:
an emitter semiconductor region;
a base semiconductor region; and
a collector semiconductor region,
wherein the collector semiconductor region is adjacent to a silicide layer that is at least partially buried beneath the collector semiconductor region, and
wherein an area of the collector semiconductor region, which is adjacent to the silicide layer, is doped by a dopant that has diffused out of the silicide layer, and
wherein the dopant is introduced over a substantial area of the silicide layer prior to the collector semiconductor region being applied over the silicide layer.

25. A method for manufacturing a semiconductor component, the method comprising the steps of:
providing a silicide layer;
depositing a dopant into the silicide layer, the dopant being deposited across a substantial surface area of the silicide layer; and
applying a semiconductor layer onto the silicide layer.

26. The method according to claim 25, wherein the semiconductor layer is formed completely over the silicide layer.

27. The method according to claim 25, wherein the dopant is an impurity that is implanted into the silicide layer or sputtered onto the silicide layer.

28. The method according to claim 25, wherein, after the semiconductor layer is applied onto the silicide layer, a high temperature diffusion process is performed to diffuse the dopant from the silicide layer into the semiconductor layer.

29. The method according to claim 28, wherein the high temperature diffusion process is performed in an independent manufacturing step.

30. The method according to claim 25, wherein the silicide layer is provided on a substrate.

31. The method according to claim 30, wherein the silicide layer is provided between the substrate and the semiconductor layer.

32. The method according to claim 30, wherein the silicide layer is provided on the substrate by sputtering, and wherein the semiconductor layer is grown on the silicide layer.

33. A semiconductor component comprising:
a substrate;
a silicide layer; and
a semiconductor layer, the silicide layer being provided between the substrate and the semiconductor layer, the semiconductor layer being formed over the silicide layer after a dopant is deposited into the silicide layer, the dopant being deposited across a substantial surface area of the silicide layer.

34. The semiconductor component according to claim 33, wherein the dopant is diffused into the semiconductor layer in a subsequent diffusion process.

35. The semiconductor component according to claim 33, wherein the semiconductor component is a transistor.
